(19) United States
(12) Patent Application Publication
(10) Pub. No.: US 2008/0296646 A1
(43) Pub. Date: Dec. 4, 2008

(54) SEMICONDUCTOR MEMORY DEVICE AND METHOD FOR FABRICATING THE SAME

(75) Inventor: Yuki YAMADA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/126,636

(22) Filed: May 23, 2008

(30) Foreign Application Priority Data
May 25, 2007 (JP) P2007-138873

(51) Int. Cl. H01L 27/108; H01L 21/8239

(52) U.S. Cl. 257/295; 438/3; 257/E27.104; 257/E21.645

(57) ABSTRACT

According to an aspect of the present invention, there is provided a semiconductor memory device including: a semiconductor substrate; a transistor that is formed on the semiconductor substrate; a ferroelectric capacitor including a bottom electrode that is formed above the semiconductor to be connected with the transistor, a ferroelectric film that is formed on the bottom electrode, and a top electrode that is formed on the ferroelectric film; a first reaction preventing film that covers a lower side surface of the ferroelectric capacitor; and a second reaction preventing film that covers an upper side surface and a top surface of the ferroelectric capacitor.

### CROSS-REFERENCE TO RELATED APPLICATIONS

This application is based upon and claims a priority from Japanese Patent Application No. 2007-138873 filed on May 25, 2007, the entire contents of which are incorporated herein by reference.

### BACKGROUND OF THE INVENTION

1. Field of the Invention

An aspect of the present invention relates to a semiconductor memory device, particularly to a semiconductor memory device having a ferroelectric capacitor or a memory cell composed of a transistor and a ferroelectric capacitor, and a method for fabricating the same.

2. Description of the Related Art

Japanese Patent No. JP-3157734-B discloses a ferroelectric memory device, i.e., a FeRAM (Ferroelectric Random Access Memory) and a method for fabricating the same. A memory cell of the ferroelectric memory device is composed of a transistor and a ferroelectric capacitor connected to the transistor. The ferroelectric capacitor includes a bottom electrode, a ferroelectric film disposed on the bottom electrode, and a top electrode disposed on the ferroelectric film.

In the fabrication process of the ferroelectric memory device, the bottom electrode, the ferroelectric film, and the top electrode are sequentially laminated on a substrate to thereby form a ferroelectric capacitor, and thereafter, a reaction preventing film is formed thereon so as to cover the ferroelectric film of the ferroelectric capacitor. The reaction preventing film is formed, for example, of a silicon nitride film or an alumina film, formed through a CVD (chemical vapor deposition) process.

In the ferroelectric memory device described above, detailed considerations on the following points are not given. Since the ferroelectric capacitor is constructed by a laminated structure of a bottom electrode, a ferroelectric film, and a top electrode, the vertical height of the side wall of the ferroelectric capacitor increases in accordance with the number of thin layers forming the laminated structure. For this reason, the reaction preventing film is formed on the side wall of the ferroelectric capacitor in a state where the aspect ratio is large; therefore, the step coverage of the reaction preventing film is degraded. That is, the surface coverage properties of the ferroelectric film are deteriorated on the side wall of the ferroelectric capacitor, whereby the function as the reaction preventing film is degraded.

On the other hand, when the reaction preventing film is made sufficiently thick on the side wall of the ferroelectric capacitor, the thickness of the reaction preventing film formed on the upper surface of the ferroelectric capacitor, that is, on the upper surface of the top electrode becomes too large. In addition, it is necessary to form a connection hole (contact hole) in the reaction preventing film in order to connect a wiring to the top electrode. However, if the reaction preventing film is too thick, the fabrication process of the connection hole is complicated to thereby decrease the fabrication process yield.

### SUMMARY OF THE INVENTION

According to an aspect of the present invention, there is provided a semiconductor memory device including: a semiconductor substrate; a transistor that is formed on the semiconductor substrate; a ferroelectric capacitor including a bottom electrode that is formed above the semiconductor to be connected with the transistor, a ferroelectric film that is formed on the bottom electrode, and a top electrode that is formed on the ferroelectric film; a first reaction preventing film that covers a lower side surface of the ferroelectric capacitor; and a second reaction preventing film that covers an upper side surface and a top surface of the ferroelectric capacitor.

According to another aspect of the present invention, there is provided a method for fabricating a semiconductor memory device, including: forming a transistor on a semiconductor substrate; forming an interlayer insulating film on the semiconductor substrate to cover the transistor; forming a plug in the interlayer insulating film to be connected with the transistor; forming a bottom electrode on the interlayer insulating film to be connected with the plug; forming a ferroelectric film on the bottom electrode; forming a first reaction preventing film to cover at least the ferroelectric film; planarizing the first reaction preventing film and the ferroelectric film to expose an upper surface of the ferroelectric film; forming a top electrode on the ferroelectric film; and forming a second reaction preventing film on the first reaction preventing film to cover a side surface and an upper surface of the upper electrode.

### BRIEF DESCRIPTION OF THE DRAWINGS

Embodiment may be described in detail with reference to the accompanying drawings, in which:

FIG. 1 is a sectional view illustrating main parts of a nonvolatile memory circuit according to a first embodiment;

FIG. 2 is a circuit diagram of the nonvolatile memory circuit according to the first embodiment;

FIG. 3 is a first sectional view showing a process step of a method for fabricating the nonvolatile memory circuit according to the first embodiment;

FIG. 4 is a second sectional view showing a process step of the method for fabricating the nonvolatile memory circuit according to the first embodiment;

FIG. 5 is a third sectional view showing a process step of the method for fabricating the nonvolatile memory circuit according to the first embodiment;

FIG. 6 is a fourth sectional view showing a process step of the method for fabricating the nonvolatile memory circuit according to the first embodiment;

FIG. 7 is a fifth sectional view showing a process step of the method for fabricating the nonvolatile memory circuit according to the first embodiment;

FIG. 8 is a sixth sectional view showing a process step of the method for fabricating the nonvolatile memory circuit according to the first embodiment;

FIG. 9 is a circuit diagram showing a modified example of the nonvolatile memory circuit according to the first embodiment;

FIG. 10 is a sectional view illustrating main parts of a nonvolatile memory circuit according to a second embodiment;

FIG. 11 is a sectional view illustrating main parts of a nonvolatile memory circuit according to a third embodiment;

FIG. 12 is a sectional view illustrating main parts of a nonvolatile memory circuit according to a fourth embodiment; and

FIG. 13 is a sectional view illustrating main parts of a nonvolatile memory circuit according to a fifth embodiment.

### DETAILED DESCRIPTION OF THE INVENTION

The embodiments will be described in detail with reference to the accompanying drawings. A first embodiment is directed to a semiconductor device having a ferroelectric capacitor, more specifically, to a semiconductor memory device (nonvolatile memory circuit) having a ferroelectric capacitor in a memory cell and capable of storing data in the ferroelectric capacitor.

### First Embodiment

### Structure of Nonvolatile Memory Circuit

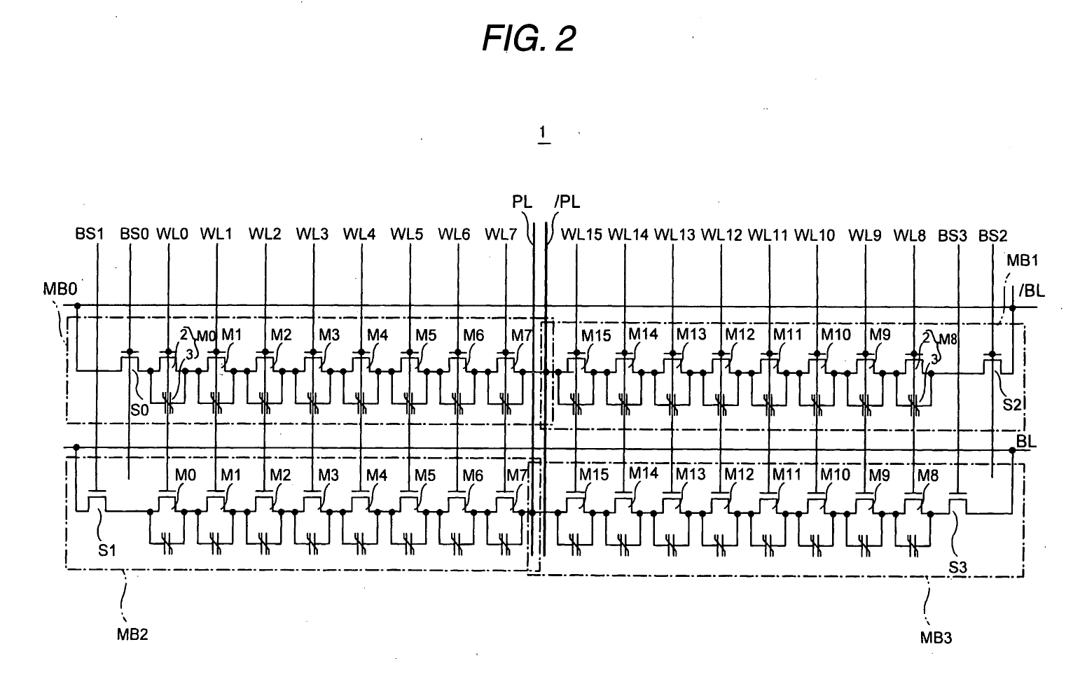

As shown in FIG. 2, a nonvolatile memory circuit 1 according to a first embodiment is a chain ferroelectric random-access memory (series connected TC unit type ferroelectric RAM). In this nonvolatile memory circuit 1, a memory cell M capable of storing 1-bit information is provided with one transistor 2 and one ferroelectric capacitor 3 electrically parallelly connected to the transistor 2. That is, one of the paired main electrodes of the transistor 2 is electrically connected to one of the electrodes of the ferroelectric capacitor 3, while the other of the paired main electrodes of the transistor 2 is electrically connected to the other of the electrodes of the ferroelectric capacitor 3. In the first embodiment, the transistor 2 is an n-channel type insulated gate field effect transistor (IGFET). Here, the term, IGFET, is used to refer to both a MOSFET (metal oxide semiconductor field effect transistor) and a MISFET (metal insulator semiconductor field effect transistor).

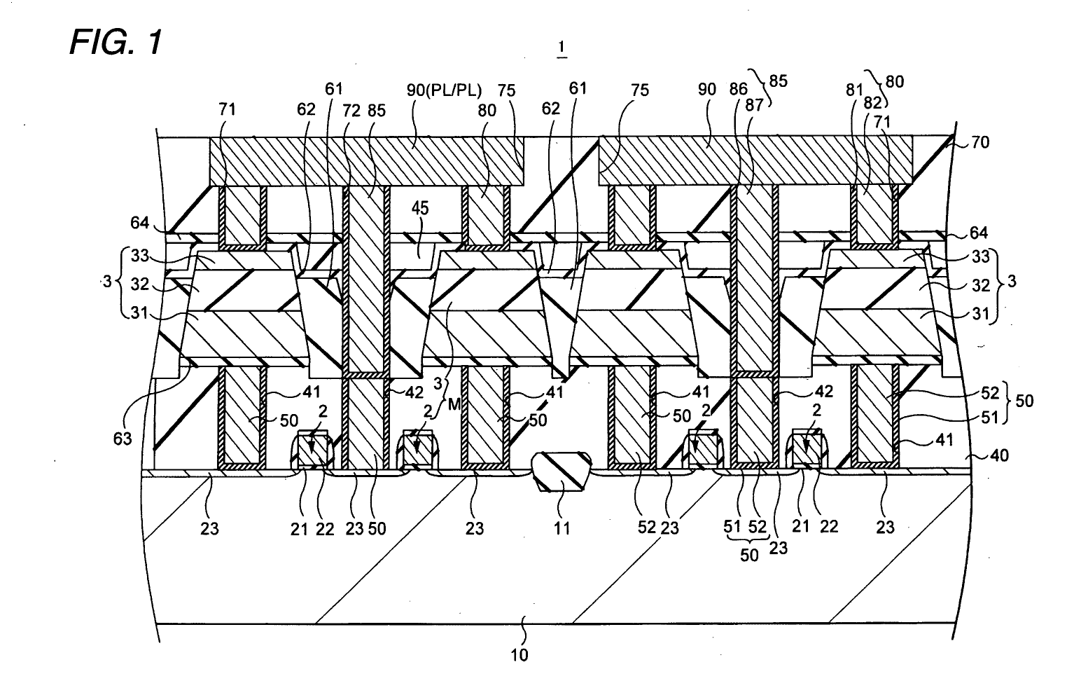

As shown in FIG. 1, the ferroelectric capacitor 3 is disposed above a main electrode region 23 at one side of the transistor 2 through an interlayer insulating film 40 interposed therebetween. The ferroelectric capacitor 3 is provided with a first electrode (bottom electrode) 31 disposed on the interlayer insulating film 40 disposed on a substrate 10, a ferroelectric film 32 disposed on the first electrode 31, and a second electrode (top electrode) 33 disposed on the ferroelectric film 32. More specifically, the first electrode 31 is disposed above the interlayer insulating film 40 with a reaction preventing film (third reaction preventing film) 63 interposed therebetween. The first electrode 31 may be formed of material such as Pt, Ir, IrO₂, or SRO (Strontium Ruthenium Oxide). The reaction preventing film 63 may be formed of material that has conductivity and prevents, mainly, oxygen diffusion, such as IrO₂, TiAlN, or TiAl. The ferroelectric film 32 is disposed on the first electrode 31. The ferroelectric film 32 can be formed of material such as PZT (Pb(Zr,Ti)O₃) or SBT (SrBi₂Ta₂O₉). The second electrode 33 is disposed on the ferroelectric film 32. The second electrode 33 can be formed of material such as Pt, Ir, IrO₂, or SRO, similar to the first electrode 31.

The first electrode 31 of the ferroelectric capacitor 3 is electrically connected to one main electrode region 32 of the transistor 2 via a plug 50 disposed thereon and the reaction preventing film 63. The plug 50 is disposed within a connection hole (via-hole) 41 formed in the interlayer insulating film 40 that disposed between the transistor 2 and the ferroelectric capacitor 3 so as to cover the transistor 2. The plug 50 is provided with a barrier metal film 51 that is provided on an inner wall and a bottom surface of the connection hole 41 and a burying conductor 52 that is provided on the barrier metal film 51 and buried in the connection hole 41. The barrier metal film 51 can be formed either of Ti and TiN. The burying conductor 52 can be formed of a metal film having high melting point, such as polysilicon film or tungsten (W).

The second electrode 33 of the ferroelectric capacitor 3 is electrically connected via a plug 80 provided thereon to a plate line 90 that is disposed above the second electrode 33. The plug 80 is disposed within a connection hole (via-hole) 71 formed in an interlayer insulating film 70 that covers the ferroelectric capacitor 3. The plug 80 is provided with a barrier metal film 81 that is provided on an inner wall and a bottom surface of the connection hole 71 and a burying conductor 82 that is provided on the barrier metal film 81 and buried in the connection hole 71. The barrier metal film 81 is formed of the same material as the barrier metal film 51 of the plug 50, and the burying conductor 82 is formed of the same material as the burying conductor 52. In the first embodiment, the plate line 90 may be formed of Cu, a Cu alloy, an Al alloy, or an Al alloy having at least one of Si and Cu added thereto.

The nonvolatile memory circuit 1 having such an arrangement is provided with a reaction preventing film (first reaction preventing film) 61 that covers a lower side surface of the ferroelectric capacitor 3 and a reaction preventing film (second reaction preventing film) 62 that covers an upper side surface and an upper surface of the ferroelectric capacitor 3. The reaction preventing films 61 and 62 basically have insulating properties, and both films are tightly contacted with each other to thereby prevent penetration of oxygen or hydrogen into the ferroelectric film 32.

In the first embodiment, the reaction preventing film is formed on the ferroelectric capacitor 3 through at least two steps. Since the lower reaction preventing film 61 is formed on the side surface of the first electrode 31 and the lower side surface of the ferroelectric film 32, an aspect ratio between the upper side surface of the ferroelectric film 32 and the side surface of the second electrode 33 and the upper surface of the second electrode 33 where the upper reaction preventing film 62 is formed is decreased. In a memory cell array, a concave portion is formed between the ferroelectric capacitors 3 of the adjacent memory cells M, and the reaction preventing film 61 is buried in this concave portion.

In the first embodiment, when the reaction preventing film 61 is formed, the height of the upper surface thereof is set to the same height as the upper surface of the ferroelectric film 32. However, according to the fabrication process of the nonvolatile memory circuit 1, since the reaction preventing film 61 is over-etched relative to the ferroelectric film 32, the height of the upper surface of the reaction preventing film 61 within the range of the side surface of the ferroelectric film 32 is slightly lower than the height of the upper surface of the ferroelectric film 32. The reaction preventing film 61 may be formed, for example, of a SiN film or an Al₂O₃ film. Moreover, in the first embodiment, although the reaction preventing film 61 is composed of a single-layer film; the present invention is not limited to this, and the reaction preventing film 61 may be composed of a laminated multi-layer film with two or more thin layers of identical materials or of different materials.

The upper reaction preventing film 62, which is formed after the lower reaction preventing film 61 have been formed, basically has insulating properties and prevents penetration of oxygen or hydrogen into the ferroelectric film 32, similar to the reaction preventing film 61. The most part (or a portion) of the side surface of the ferroelectric film 32 is firmly and securely covered by the reaction preventing film 61, and the reaction preventing film 61 is buried between the adjacent ferroelectric capacitors 3, whereby the ferroelectric capacitor 3 has a smooth step. For example, by burying the reaction preventing film 61, an effective height of the side surface of the ferroelectric capacitor 3 where the reaction preventing film 62 is formed can be set to 80 nm to 100 nm. Moreover, when the gap between the adjacent ferroelectric capacitors 3 is set to 50 nm, it is possible to provide a low aspect ratio of 1.6 to 2.0.

Therefore, in the ferroelectric capacitor 3 having a smooth step thank to the reaction preventing film 61, since the most part of the side surface of the ferroelectric film 32 is covered by the reaction preventing film 61, it is not necessary for the reaction preventing film 62 to have a thickness at the side surface of the ferroelectric film 32 sufficient to prevent penetration of oxygen or hydrogen thereto, and thus the thickness of the reaction preventing film 62 can be decreased. In particular, the thickness of the reaction preventing film 62 at the upper surface of the second electrode 33 can be decreased. The reaction preventing film 62 may be formed, for example, of Si₃N₄ film or Al₂O₃. Moreover, in the first embodiment, although the reaction preventing film 62 is composed of a single-layer film; the present invention is not limited to this, and the reaction preventing film 62 may be composed of a laminated multi-layer film with two or more thin layers of identical materials or of different materials.

Another reaction preventing film (fourth reaction preventing film) 64 is provided on the reaction preventing film (second reaction preventing film) 62 above the ferroelectric capacitor 3. The reaction preventing film 64 can be formed, for example, of a SiN film or an Al₂O₃ film.

### [Method for Fabricating Nonvolatile Memory Circuit]

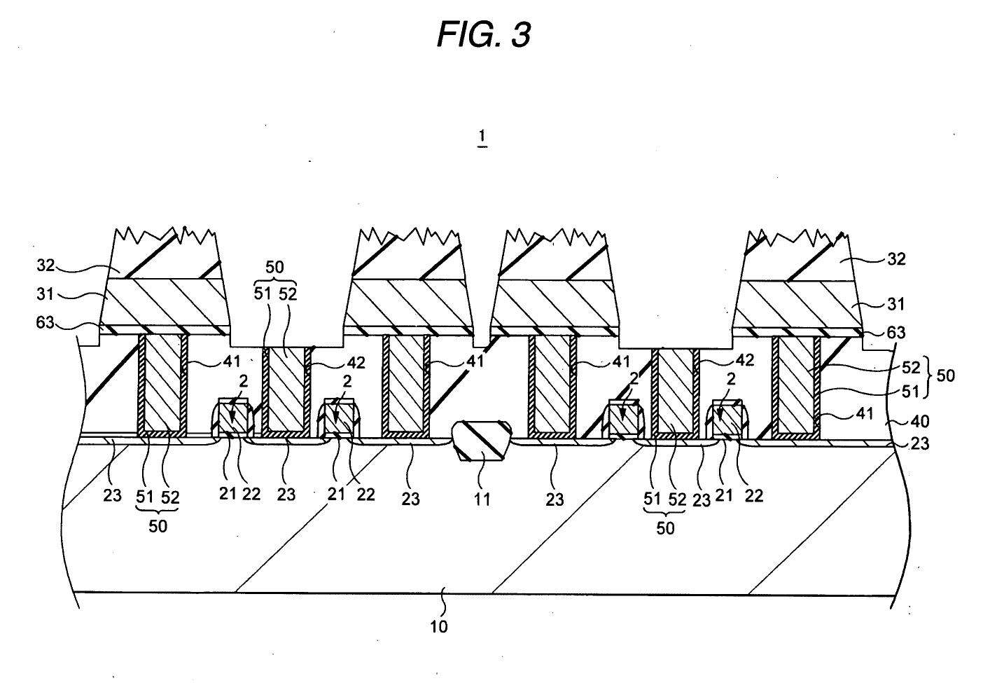

A method for fabricating the nonvolatile memory circuit 1 described above will be described. First, a substrate 10 is prepared, and a device isolation region 11 is formed in a non-active region of the substrate 10 (see FIG. 3). After the device isolation region 11 is formed, transistors 2 of the memory cells M are formed in an active region of the substrate 10 (see FIG. 3).

The method for fabricating the transistor 2 is as follows. First, a gate insulating film 21 is formed on the surface of the active region of the substrate 10, and subsequently, a control electrode 22 is formed on the gate insulating film 21. The gate insulating film 21 can be formed, for example, of several layers of a single-layer film made of SiO₂, Si₃N₄, or SiON, or of a multi-layer film with two or more layers of the single-layer film. The control electrode 22 can be formed, for example, of several layers of a single-layer film made of polysilicon, high-melting point metal, or high-melting point metal silicide, or of a laminated multi-layer film with a high-melting point metal film or a high-melting point metal silicide film on a polysilicon film. After the control electrode 22 is formed, a pair of main electrode regions 23 is formed on a surface portion of the active region of the substrate 10 at both sides of the control electrode 22. The main electrode regions 23 is formed by implanting n-type impurities onto a peripheral portion of the active region while using the control electrode 22 or a mask used to pattern the control electrode 22 as an ion implantation mask. In the first embodiment, although the structure is not clearly shown, the transistor 2 has an extension structure or an LDD (lightly doped drain) structure.

Subsequently, on the entire surface of the substrate 10, an interlayer insulating film 40 is formed to cover the transistor 2 (see FIG. 3). The interlayer insulating film 40 may be formed, for example, of several layers of a single-layer film, made of a SiO₂ film, a PSG film, a BPSG film, or a TEOS film, formed through a CVD process, or of a laminated multi-layer film with two or more layers of the single-layer film. Alternatively, the interlayer insulating film 40 may be a multi-layer film composed of an insulating film formed through a CVD process and an insulating film formed through a sputtering process.

Subsequently, a plug 50 is formed in the interlayer insulating film 40 on the main electrode regions 23 of the transistor 2 (see FIG. 3). When forming the plug 50, first, a connection hole 41 is formed in the interlayer insulating film 40 on the main electrode region 23 at one side of the transistor 2 while a connection hole 42 is formed in the interlayer insulating film 40 on the main electrode region 23 at the other side of the transistor 2. Subsequently, a barrier metal film 51 and a burying conductor 52 are sequentially laminated onto the connection holes 41 and 42 to thereby form the plug 50. The barrier metal film 51 prevents metal constituting the burying conductor 52 of the plug 50 from penetrating into the main electrode regions 23 of the transistor 2. The barrier metal film 51 can be formed, for example, of a Ti film or a TiN film. The burying conductor 52 can be formed of material such as a high-melting point metal film formed through a CVD process or a sputtering process, or a polysilicon film formed through a CVD process. The barrier metal film 51 and the burying conductor 52 are planarized by a CMP (chemical mechanical polishing) process after they are formed, and therefore, they are buried only within the connection hole 41 or 42. Moreover, in the method for fabricating the nonvolatile memory circuit 1 according to the first embodiment, the plug 50 formed on the main electrode region 23 at one side of the transistor 2 is fabricated at the same fabrication process step as the plug 50 formed on the main electrode region 23 at the other side of the transistor 2. However, the present invention is not limited to this but the plug 50 may be fabricated at different fabrication process steps.

Next, a reaction preventing film (third reaction preventing film) 63 is formed on the entire surface of the interlayer insulating film 40 including the plug 50 (see FIG. 3). The reaction preventing film 63 prevents penetration of oxygen from a lower side of the ferroelectric capacitor 3 into the ferroelectric film 32 of the ferroelectric capacitor 3. The reaction preventing film 63 may be formed of a single layer or a laminated layer made of an Ir film, an IrO₂ film, a TiAlN film, or a TiAl film. For example, when the reaction preventing film 63 is formed of a TiAlN film, the thickness is set to about 20 nm to about 40 nm.

Next, a first electrode 31 of the ferroelectric capacitor 3 is formed on the reaction preventing film 63, and a ferroelectric film 32 is formed on the first electrode 31 (see FIG. 3). The first electrode 31 may be formed of a single layer or a laminated layer made of a Pt film, an Ir film, an IrO₂ film, or a SRO film, and such a thin film may be formed through a sputtering process or a CVD process. For example, when the first electrode 31 is formed of an Ir film, the thickness is set to about 100 nm to about 150 nm. The ferroelectric film 32 can be formed, for example, of PZT or SBT, and such a thin film may be formed through a sputtering processor a MOCVD process. For example, when the ferroelectric film 32 is formed of PZT, the thickness is set to about 50 nm to about 150 nm.

As shown in FIG. 3, the ferroelectric film 32, the first electrode 31, and the reaction preventing film 63 are patterned to form a part of the ferroelectric capacitor 3. That is, in a formation region of the ferroelectric capacitor 3, the reaction preventing film 63, the first electrode 31, and the ferroelectric film 32 are left while the reaction preventing film 63 and the like outside the formation region are removed. The patterning may be conducted using an etching mask formed through a photolithographic process by a reactive ion etching (RIE) using ArCl, CF₄, or the like as an etching gas.

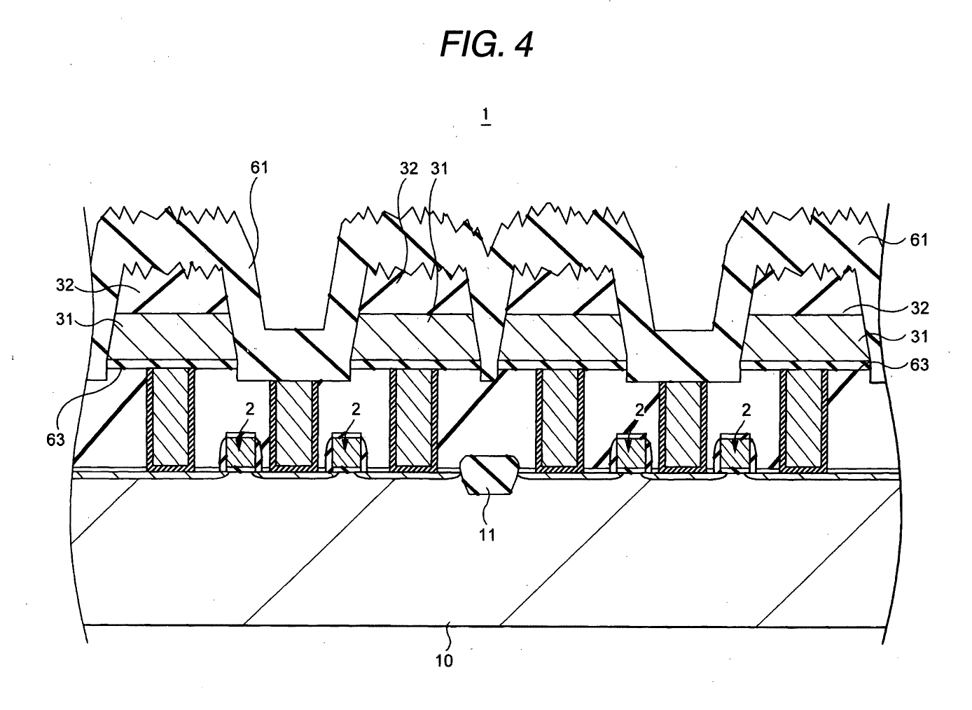

As shown in FIG. 4, as a first step, on the entire surface of the interlayer insulating film 40, a reaction preventing film (first reaction preventing film) 61 is formed so as to cover at least an upper surface and a side surface of the ferroelectric film 32 and a side surface of the first electrode 31. The reaction preventing film 61 may be formed of a Si₃N₄ film or an Al₂O₃ film formed through a sputtering process or a CVD process. As described above, the reaction preventing film 61 prevents penetration of oxygen or hydrogen into the ferroelectric film 32. In the first embodiment, the reaction preventing film 61 is formed to completely bury the narrowest portion between the formation portions of the ferroelectric capacitors 3. By forming the reaction preventing film 61, the effective height of the ferroelectric capacitor 3 when forming a reaction preventing film (second reaction preventing film) 62 thereon can be decreased to about one half to about one third of its original height as compared with the case where only one reaction preventing film is formed on the ferroelectric capacitor 3. In the first embodiment, although the reaction preventing film 61 is a single-layer film, the present invention is not limited to this but the reaction preventing film 61 may be a laminated multi-layer film with several layers of the single-layer film.

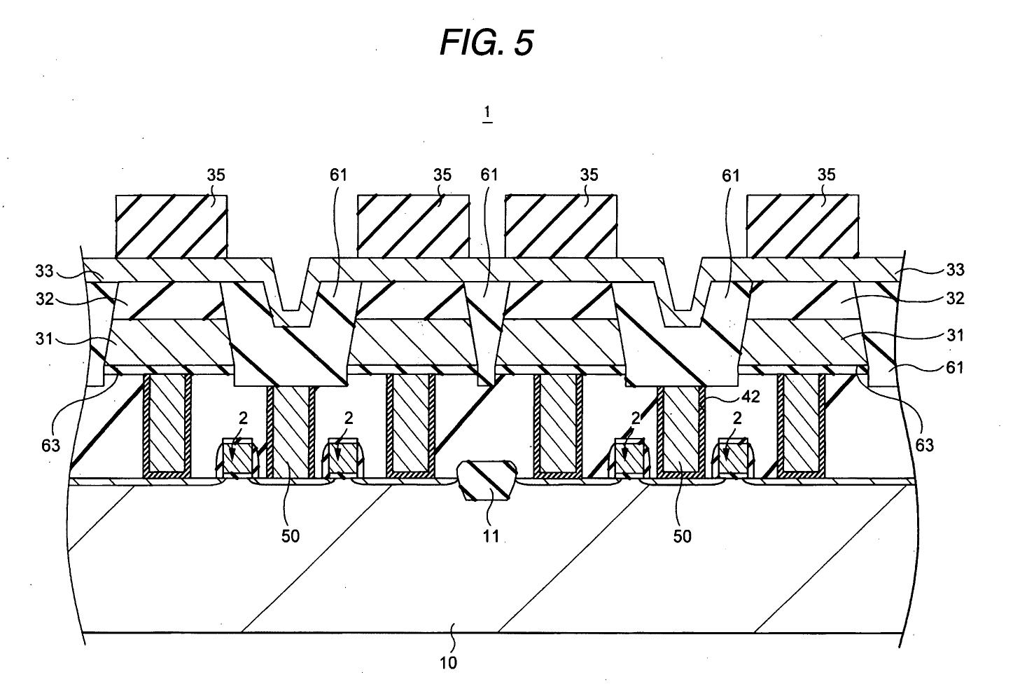

Subsequently, the surface of the reaction preventing film 61 is planarized (see FIG. 5). The planarization of the reaction preventing film 61 may be conducted by a CMP process in such a way that the surface of the planarized reaction preventing film 61 has the same height as the upper surface of the ferroelectric film 32.

A second electrode 33 is formed over the entire surface of the substrate 10 including the ferroelectric film 32 and the reaction preventing film 61 (see FIG. 5). The second electrode 33 may be formed of a single layer or a laminated layer made of a Pt film, an Ir film, an IrO₂ film, or a SRO film, similar to the first electrode 31, and such a thin film may be formed through a sputtering process or a CVD process. For example, when the second electrode 33 is formed of an Ir film, the thickness is set to about 20 nm to about 100 nm.

As shown in FIG. 5, a mask 35 is formed to perform patterning on the second electrode 33. The mask 35 may be an etching mask (soft mask) formed through a photolithographic process, or an etching mask (hard mask) formed from a TEOS film or a TiAlN film.

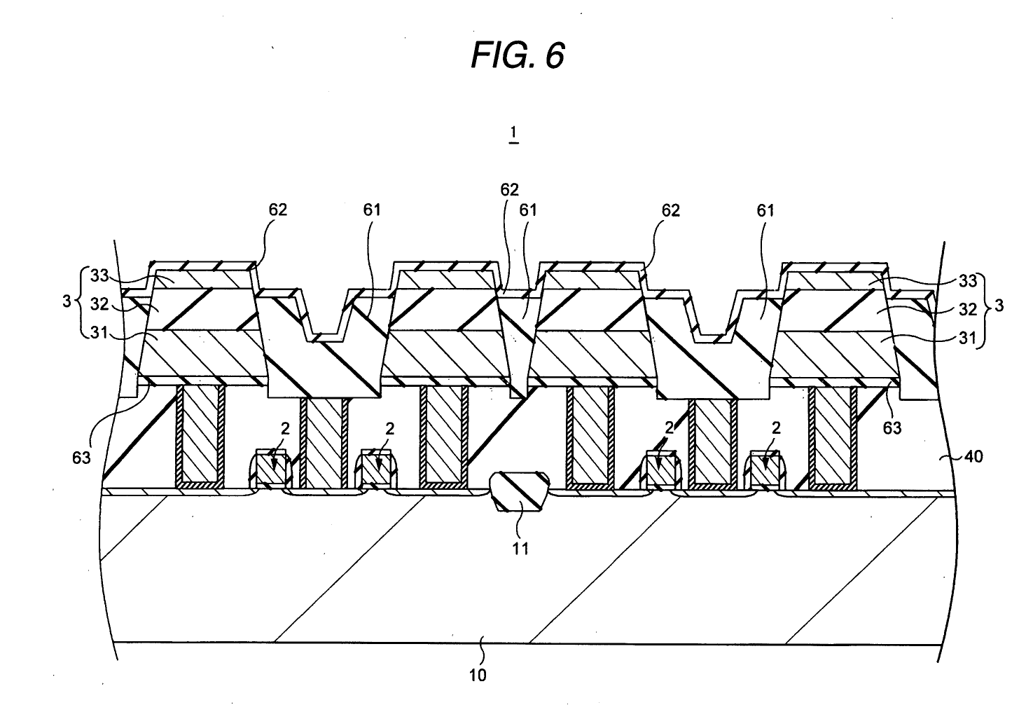

Next, the second electrode 33 is patterned using the mask 35 (see FIG. 6). By patterning the second electrode 33, the ferroelectric capacitor 3 having the first electrode 31, the ferroelectric film 32, and the second electrode 33 is completed. In the patterning of the second electrode 33, a RIE process using ArCl or CF₄ as an etching gas may be used.

As shown in FIG. 6, a reaction preventing film (second reaction preventing film) 62 is formed as a second step over the entire surface of the substrate 10 including the ferroelectric capacitor 3 and the reaction preventing film 61. More specifically, the reaction preventing film 62 is formed over the entire surface of the substrate 10 including an upper surface and a side surface of the second electrode 33 of the ferroelectric capacitor 3, an upper surface of the reaction preventing film 61, and a side surface (a shoulder portion exposed by over-etching) of the ferroelectric film 32 slightly exposed from between the second electrode 33 and the reaction preventing film 61. The reaction preventing film 62 may be a Si₃N₄ film formed through a CVD process or an Al₂O₃ film formed through a sputtering process or an ALD (atomic layer deposition) process.

As described above, the reaction preventing film 62 prevents penetration of oxygen or hydrogen into the ferroelectric film 32. The reaction preventing film 61 is previously formed under the reaction preventing film 62. The reaction preventing film 61 covers the most part of the exposed side surface of the ferroelectric film 32, and decreases the aspect ratio of the ferroelectric capacitor 3 for forming the reaction preventing film 62. As described above, the aspect ratio can be decreased to about 1.6 to about 2.0 by forming the reaction preventing film through two steps. Therefore, the reaction preventing film 62 can be formed to a desired thickness on the side surface of the ferroelectric film 32, and the thickness of the reaction preventing film 62 can be maintained within a suitable range on the upper surface of the second electrode 33. The peripheral portion of the ferroelectric capacitor 3 according to the first embodiment is completely covered by the reaction preventing film (third reaction preventing film) 63 below the first electrode 31, the reaction preventing film (first reaction preventing film) 61 that covers the side surface of the first electrode 31 and the most part of the side surface of the ferroelectric film 32, and the reaction preventing film (second reaction preventing film) 62 that covers a remaining part of the side surface of the ferroelectric film 32 and the side surface and the upper surface of the second electrode 33.

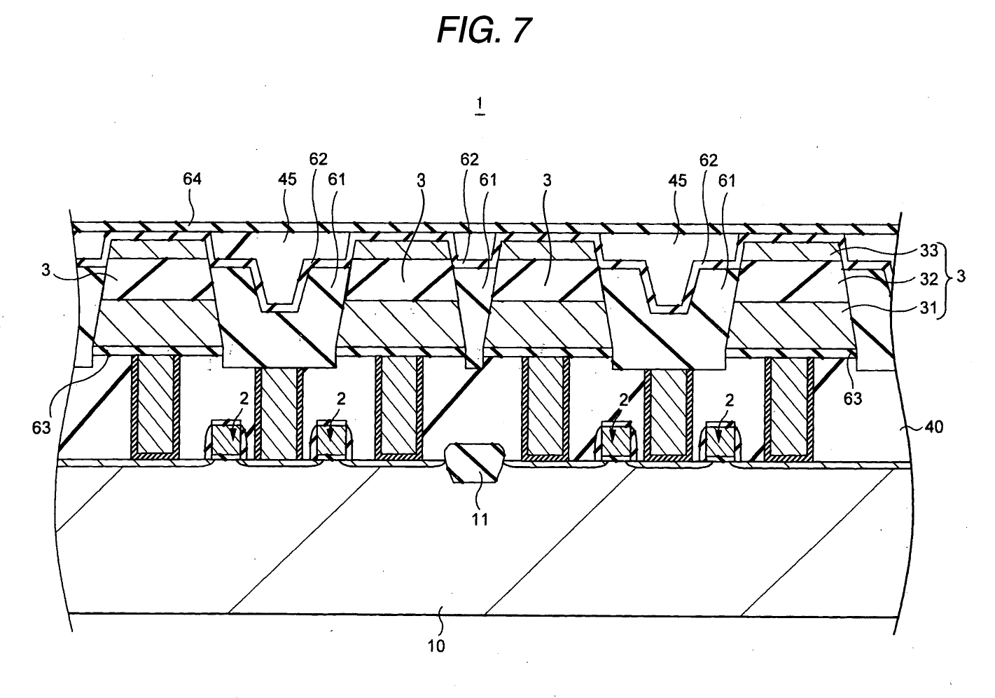

Next, an interlayer insulating film 45 is formed over the entire surface of the substrate 10 including the reaction preventing film 62 (see FIG. 7). The interlayer insulating film 45 may be formed of a BPSG film formed through a CVD process or of a TEOS film formed through a CVD process. The interlayer insulating film 45 is formed to a thickness so as to provide a smooth step between the ferroelectric capacitors 3 (to bury the concave portions) and to planarize the surface. Subsequently, the interlayer insulating film 45 is planarized by a CMP process. As a result, the interlayer insulating film 45 is buried in the concave portions between the adjacent ferroelectric capacitors 3.

As shown in FIG. 7, a reaction preventing film (fourth reaction preventing film) 64 is formed over the entire surface of the substrate 10 including the reaction preventing film 62 on the second electrode 33 of the ferroelectric capacitor 3 and the interlayer insulating film 45. The reaction preventing film 64 may be formed of SiN or Al₂O₃ having barrier properties against hydrogen. When the reaction preventing film 64 is formed of an Al₂O₃ film, the thickness is set to about 5 nm to about 40 nm.

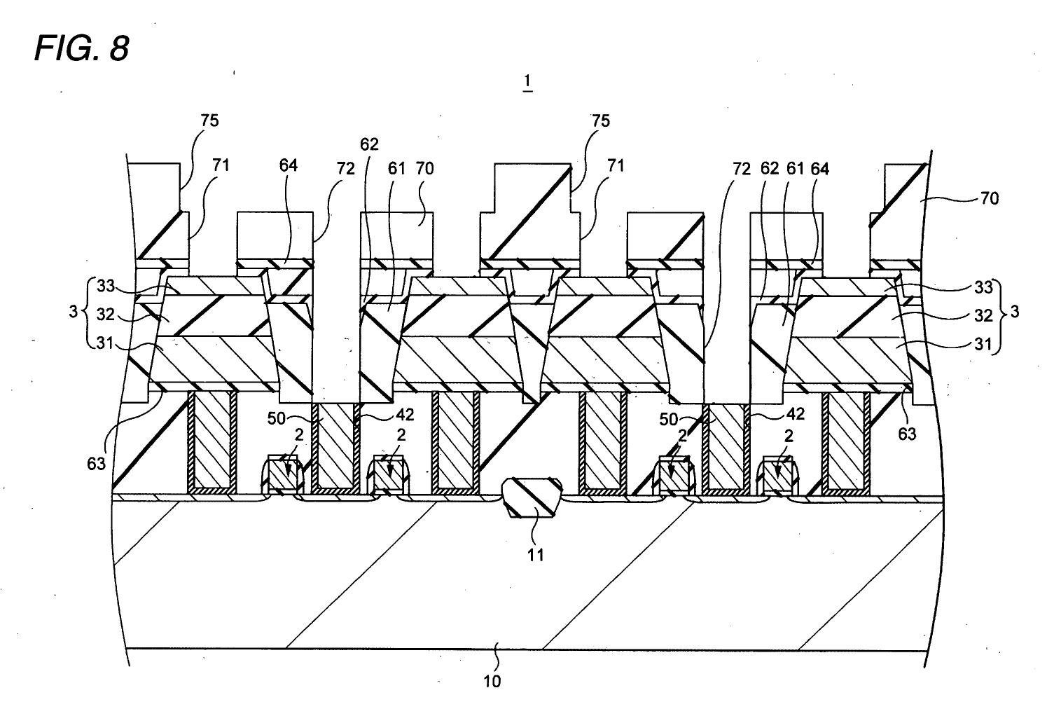

Next, an interlayer insulating film 70 is formed over the entire surface of the substrate 10 including the reaction preventing film 64 (see FIG. 8). The interlayer insulating film 70 may be formed, for example, of a BPSG film or a TEOS film, similar to the interlayer insulating film 45 described above. Subsequently, as shown in FIG. 8, a groove 75 for forming a plate line 90, a connection hole 71 for forming a plug 80, and a connection hole 72 for forming a plug 85 are formed in the interlayer insulating film 70 (see FIG. 1). The groove 75 and the connection holes 71 and 72 can be formed by anisotropic etching such as RIE using a mask formed through a photolithographic process.

Here, the connection hole 71 is formed by etching and removing the reaction preventing film (second reaction preventing film) 62 on the second electrode 33 of the ferroelectric capacitor 3, the reaction preventing film (fourth reaction preventing film) 64, and the interlayer insulating film 70. In this embodiment, the reaction preventing film 62 can have a thickness suitable for opening the hole 71 on the top electrode 33; therefore, the connection hole 71 can be easily fabricated.

Subsequently, a plug 80 is formed in the connection hole 71, and a plug 85 is formed in the connection hole 72. The plug 80 is formed by forming a barrier metal film 81 along an inner wall and a bottom wall of the connection hole 71, and thereafter, burying the connection hole 71 with a burying conductor 82 through the barrier metal film 81. The plug 85 is formed by forming a barrier metal film 86 along an inner wall and a bottom surface of the connection hole 72, and thereafter, burying the connection hole 72 with a burying conductor 87 through the barrier metal film 86. In the first embodiment, although the plug 80 is formed at the same fabrication process step as the plug 85, the present invention is not limited to this and the plug 80 may be formed at different fabrication process step from the plug 85.

As described above in connection with FIG. 1, the plate line 90 buried in the groove 75 of the interlayer insulating film 70 is formed. Upon completion of a series of the fabrication process steps, the nonvolatile memory circuit 1 according to the first embodiment is obtained.

### Characteristics of First Embodiment

In the nonvolatile memory circuit 1 having such an arrangement according to the first embodiment, since the side surfaces of the ferroelectric capacitor 3, particularly, the exposed side surfaces of the ferroelectric film 32 are covered by the reaction preventing film (first reaction preventing film) 61 and the reaction preventing film (second reaction preventing film) 62, which are formed through two steps, the exposed side surface of the ferroelectric film 32 can be securely covered by the reaction preventing films 61 and 62 while decreasing the thickness of the reaction preventing film 62 on the second electrode 33. Therefore, penetration of oxygen or hydrogen into the ferroelectric film 32 and the interfaces thereof can be prevented to thereby improve the characteristics of the ferroelectric capacitor 3. Furthermore, since the connection hole 71 for forming the plug 80 between the plate line 90 and the second electrode 33 of the ferroelectric capacitor 3 can be easily formed, the fabrication process yield of the nonvolatile memory circuit 1 can be improved.

### Modified Example

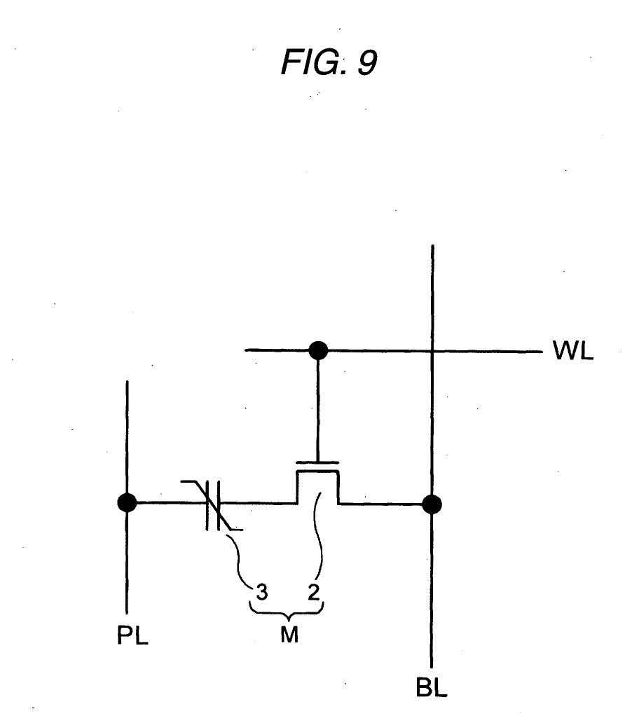

In the nonvolatile memory circuit 1 according to the first embodiment, although an example of a series connected TC unit type ferroelectric RAM has been described, the present invention is not limited to this but can be applied to a conventional FeRAM. In a nonvolatile memory circuit 1 having the conventional FeRAM structure, as shown in FIG. 9, a memory cell M capable of storing 1-bit information is disposed at an intersection of a bit line BL, a plate line PL, and a word line WL. In the memory cell M, a transistor 2 and a ferroelectric capacitor 3 are connected in series. Although only the memory cell M for one bit is shown in FIG. 9, a plurality of memory cells M are arranged in matrix so as to extend along the bit lines BL and the word lines WL.

### Second Embodiment

A second embodiment is directed to an example that improves reliability of the electrical connection between the transistor 2 of the memory cell M and the plate line 90 in the nonvolatile memory circuit 1 according to the first embodiment described above. In the second and subsequent embodiments, those parts identical or similar to those of the first embodiment will be denoted by the same or similar reference numerals, and thus redundant description thereof will be omitted.

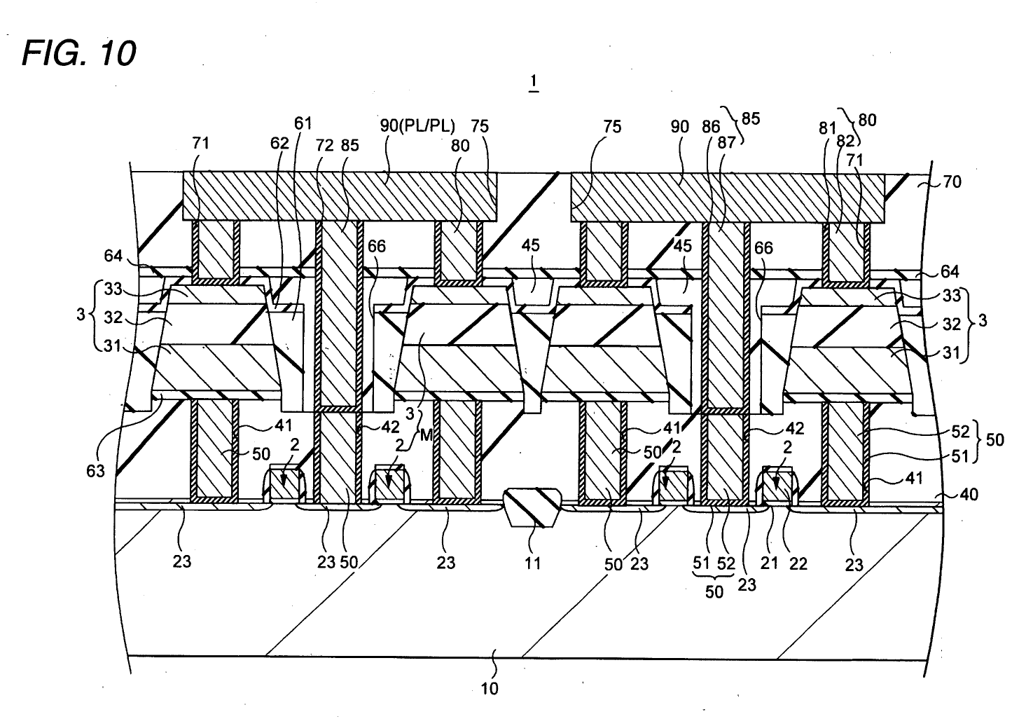

In the nonvolatile memory circuit 1 according to the second embodiment, as shown in FIG. 10, the peripheral portion of the plug 85 that electrically connects the main electrode regions 23 of the transistor 2 and the plate line 90 to each other is separated from the reaction preventing film (first reaction preventing film) 61 and the reaction preventing film (second reaction preventing film) 62. That is, a region 66 is formed by partially removing the reaction preventing films 61 and 62 on one main electrode region 23 of the transistor 2; a connection hole 72 having the opening size smaller than that of the region 66 is formed therein; and a plug 85 is formed in the connection hole 72.

In the method for fabricating the nonvolatile memory circuit 1, after the opening 66 is formed in the reaction preventing films 61 and 62, the interlayer insulating film 45 is buried in the opening 66, and the connection hole 72 of the plug 85 is formed in the interlayer insulating film 45 buried in the opening 66. That is, since the interlayer insulating film 45 is buried in the opening 66 in which the plug 85 is formed, it is not necessary to etch the reaction preventing films 61 and 62 when forming the connection hole 72.

In the nonvolatile memory circuit 1 having such an arrangement according to the second embodiment, since the reaction preventing films 61 and 62 are provided on the side surfaces of the ferroelectric capacitor 3, particularly, the exposed side surfaces of the ferroelectric film 32, it is possible to obtain the same advantage as obtainable from the nonvolatile memory circuit 1 according to the first embodiment. Furthermore, since the connection hole 72 for forming the plug 85 between the plate line 90 and the main electrode regions 23 of the transistor 2 can be formed easily and securely, the fabrication process yield of the nonvolatile memory circuit 1 can be improved.

### Third Embodiment

A third embodiment is directed to an example that increases the capacitance of the ferroelectric capacitor 3 in the nonvolatile memory circuit 1 according to the first embodiment described above.

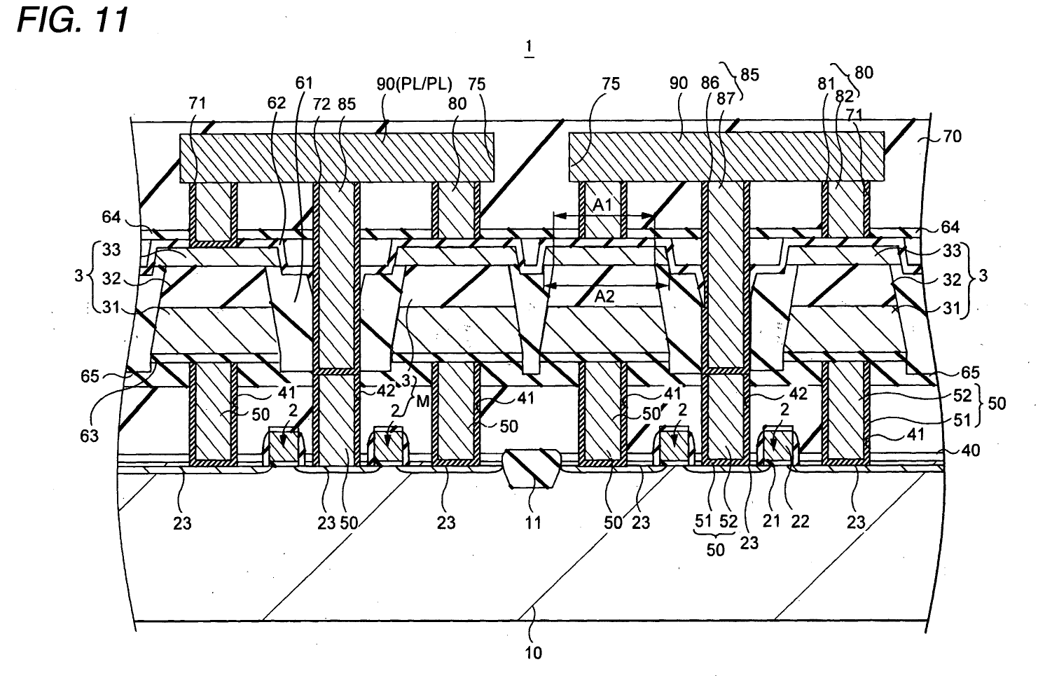

In the nonvolatile memory circuit 1 according to the third embodiment, as shown in FIG. 11, the area A2 of a lower surface (bottom surface) of the second electrode 33 is set larger than the area A1 of the upper surface of the ferroelectric film 32 of the ferroelectric capacitor 3. In the method for fabricating the nonvolatile memory circuit 1, as described above in connection with the first embodiment, since the second electrode 33 is patterned at a different patterning process from that of the ferroelectric film 32, fabrication misalignment may occur in the second electrode 33 relative to the ferroelectric film 32. That is, the area A2 of the lower surface of the second electrode 33 is set larger than the area A1 of the upper surface of the ferroelectric film 32 so that the upper surface of the ferroelectric film 32 is fully covered by the lower surface of the second electrode 33 and the contact surface therebetween is not changed even in the presence of the misalignment, i.e., by taking into consideration the misalignment amount.

In the nonvolatile memory circuit 1 having such an arrangement according to the third embodiment, since the size of the contact surface between the second electrode 33 and the ferroelectric film 32 of the ferroelectric capacitor 3 of the memory cell M does not change even in the presence of the misalignment, there is no change in the polarization amount of the ferroelectric capacitor 3. That is, it is possible to prevent decrease in the polarization amount of the ferroelectric capacitor 3 due to the misalignment. As a result, it is possible to secure a sufficient signal amount of the ferroelectric capacitor 3 and to prevent characteristics variation between wafers during device fabrication. Although the third embodiment was described and illustrated with reference to the nonvolatile memory circuit 1 according to the first embodiment, the third embodiment may be applied to the nonvolatile memory circuit 1 according to the second embodiment.

### Fourth Embodiment

A fourth embodiment is directed to an example that prevents penetration of oxygen or hydrogen into the ferroelectric film 32 of the ferroelectric capacitor 3 from the bottom surface thereof, in the nonvolatile memory circuit 1 according to the first embodiment described above.

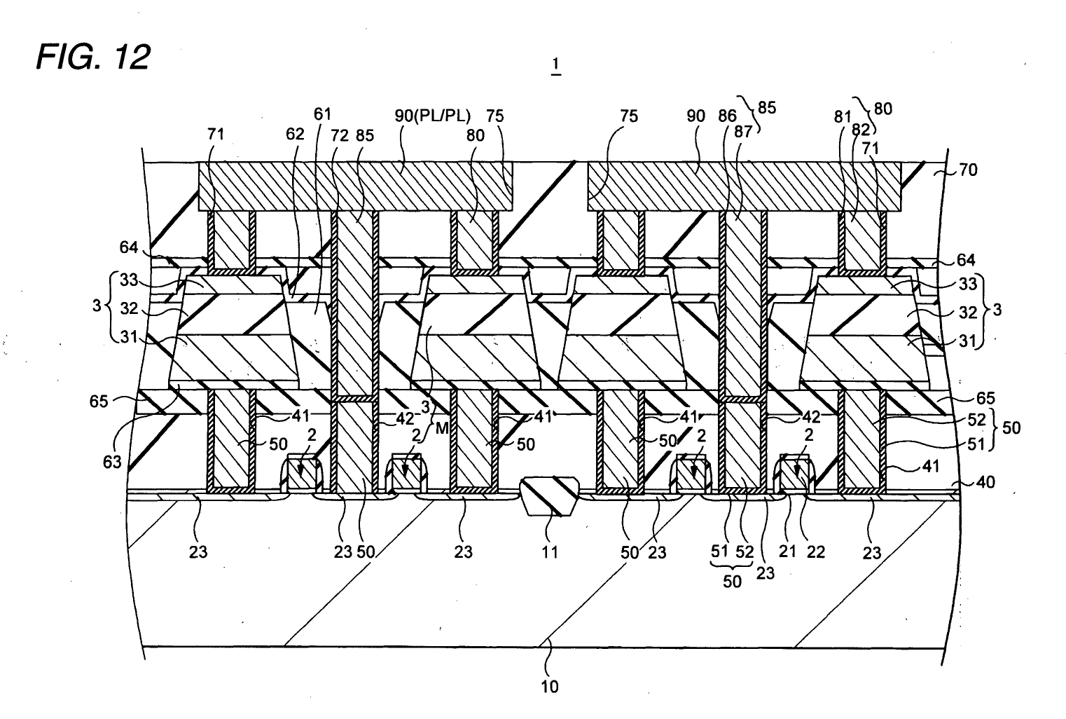

In the nonvolatile memory circuit 1 according to the fourth embodiment, as shown in FIG. 12, a reaction preventing film (fifth reaction preventing film) 65 is provided under the ferroelectric capacitor 3 between the interlayer insulating film 40 and the first electrode 31 (more specifically, the reaction preventing film 63) of the ferroelectric capacitor 3. The reaction preventing film 65 can prevent penetration of oxygen and/or hydrogen into the ferroelectric film 32 of the ferroelectric capacitor 3 from the bottom face thereof. In the fourth embodiment, the reaction preventing film 65 can be formed of an Al₂O₃ film having a thickness of about 5 nm to 20 nm and having barrier properties against oxygen and hydrogen.

In the nonvolatile memory circuit 1 having such an arrangement according to the fourth embodiment, since the reaction preventing film 65 is provided under the ferroelectric capacitor 3, it is possible to prevent penetration of oxygen and/or hydrogen into the ferroelectric film 32 of the ferroelectric capacitor 3. Therefore, the ferroelectric capacitor 3 can exhibit and maintain good characteristics. Although the fourth embodiment was described and illustrated with reference to the nonvolatile memory circuit 1 according to the first embodiment, the fourth embodiment may be applied to the nonvolatile memory circuit 1 according to the second or third embodiment.

### Fifth Embodiment

A fifth embodiment is directed to an example that improves connection reliability of the electrical connection portion between the plate line 90 and the main electrode regions 23 of the transistor 2 and the electrical connection portion between the plate line 90 and the second electrode 33 of the ferroelectric capacitor 3 in the nonvolatile memory circuit 1 according to the first embodiment described above.

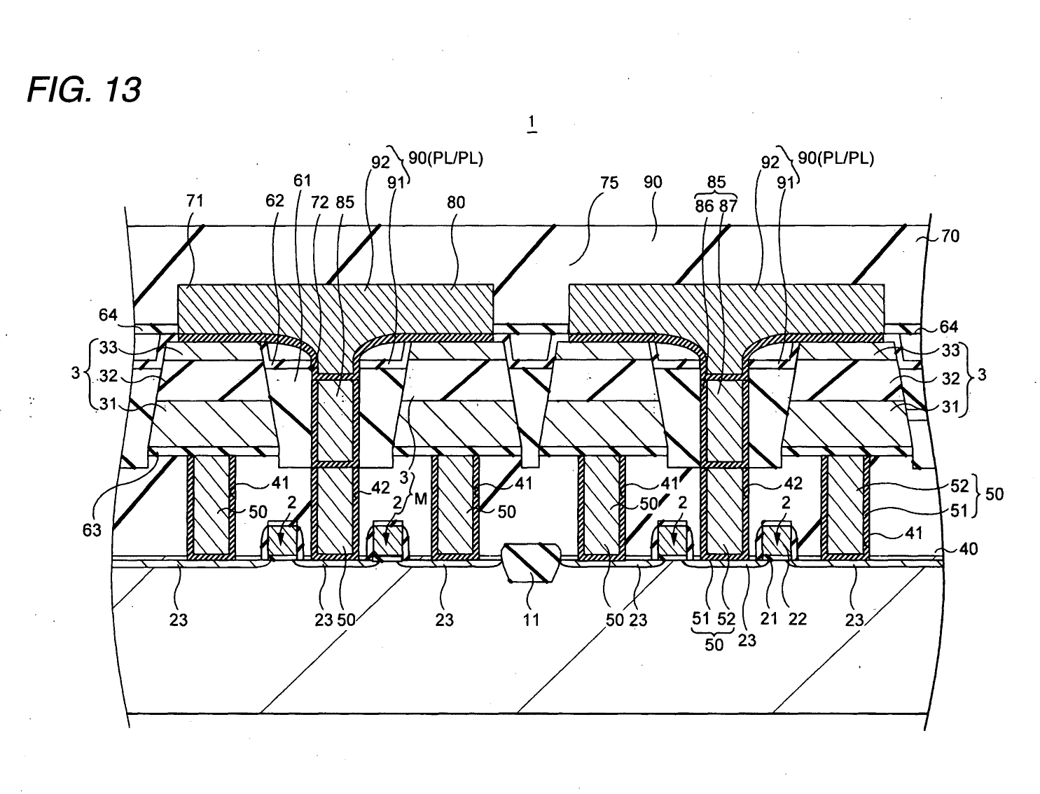

In the nonvolatile memory circuit 1 according to the fifth embodiment, as shown in FIG. 13, the plate line 90 is directly connected to the second electrode 33 of the ferroelectric capacitor 3 in a state where the reaction preventing film (second reaction preventing film) 62 and the reaction preventing film (fourth reaction preventing film) 64 on the second electrode 33 are removed. Since the second electrode 33 can be electrically connected to the plate line 90 with a relatively large area, specifically with an area larger than the surface area of the plug 80, it is possible to improve connection reliability between them.

Furthermore, since the plug 80 is not used in the connection between the plate line 90 and the second electrode 33 of the ferroelectric capacitor 3, it is possible to decrease the height of the plug 85. That is, since the aspect ratio of the connection portion between the plate line 90 and one main electrode region 23 of the transistor 2 can be decreased, it is possible to improve the connection reliability between them. In the fifth embodiment, a connection hole is formed in the reaction preventing films 62 and 64 so as to extend over the second electrode 33 of the ferroelectric capacitor 3 to above the main electrode regions 23 (above the plug 85) of the transistor 2, and the plate line 90 is connected to the second electrode 33 and the plug 85 via this connection hole.

In addition, in the fifth embodiment, the plate line 90 includes a barrier metal film 91 and a wiring metal film 92 laminated on the barrier metal film 91.

In the nonvolatile memory circuit 1 having such an arrangement according to the fifth embodiment, it is possible to improve the connection reliability of the connection portion between the plate line 90 and the main electrode regions 23 of the transistor 2 and the connection portion between the plate line 90 and the second electrode 33 of the ferroelectric capacitor 3. Although the fifth embodiment was described and illustrated with reference to the nonvolatile memory circuit 1 according to the first embodiment, the fifth embodiment may be applied to the nonvolatile memory circuit 1 according to any one of the second to fourth embodiments.

### Other Embodiments

The present invention is not limited to the embodiments described above. For example, although the embodiments were described and illustrated with reference to the nonvolatile memory circuit 1 provided with the memory cell M having the transistor 2 and the ferroelectric capacitor 3, the present invention can be widely applied to a semiconductor device having the ferroelectric capacitor 3.

According to an aspect of the present invention, by forming a reaction preventing film having excellent coverage properties, deterioration of a ferroelectric capacitor during a device fabrication process steps is prevented, whereby a semiconductor memory device capable of improving the characteristics of a ferroelectric capacitor can be provided. According to another aspect of the present invention, a method for fabricating a semiconductor memory device capable of improving the characteristics of a ferroelectric capacitor and securing the fabrication process yield of a contact hole.

What is claimed is:

1. A semiconductor memory device comprising:
a semiconductor substrate;
a transistor that is formed on the semiconductor substrate;
a ferroelectric capacitor including
a bottom electrode that is formed above the semiconductor to be connected with the transistor,
a ferroelectric film that is formed on the bottom electrode, and
a top electrode that is formed on the ferroelectric film;
a first reaction preventing film that covers a lower side surface of the ferroelectric capacitor; and
a second reaction preventing film that covers an upper side surface and a top surface of the ferroelectric capacitor.

2. The semiconductor memory device according to claim 1,
wherein an upper end of the first reaction preventing film is located below an interface between the top electrode and the ferroelectric film, and
wherein the second reaction preventing film is located above the first reaction preventing film.

3. The semiconductor memory device according to claim 1,
wherein the first and the second reaction preventing films have an insulating property and prevent a penetration of oxygen or hydrogen into the ferroelectric film.

4. The semiconductor memory device according to claim 1 further comprising:
a plate line that is connected with the upper electrode; and
a plug that is connected with the plate line and the transistor.

5. The semiconductor memory device according to claim 4,
wherein the plug is disposed in the first reaction preventing film.

6. The semiconductor memory device according to claim 4 further comprising:
an interlayer insulating film that is formed in the first reaction preventing film,
wherein the plug is disposed in the interlayer insulating film.

7. The semiconductor memory device according to claim 1,
wherein a bottom surface area of the top electrode is set larger than a top surface area of the ferroelectric film.

8. The semiconductor memory device according to claim 1 further comprising:
a third reaction preventing film that is disposed below the bottom electrode.

9. The semiconductor memory device according to claim 8 further comprising:
a fourth reaction preventing film that is disposed on the second reaction preventing film.

10. The semiconductor memory device according to claim 9 further comprising:
a fifth reaction preventing film that is disposed below the third reaction preventing film.

11. The semiconductor memory device according to claim 10,
wherein the fourth and the fifth reaction preventing films have an insulating property and prevent a penetration of oxygen or hydrogen into the ferroelectric film, and
wherein the third reaction preventing film has a conducting property and prevents an oxygen diffusion.

12. A method for fabricating a semiconductor memory device, comprising:
forming a transistor on a semiconductor substrate;
forming an interlayer insulating film on the semiconductor substrate to cover the transistor;
forming a plug in the interlayer insulating film to be connected with the transistor;
forming a bottom electrode on the interlayer insulating film to be connected with the plug;
forming a ferroelectric film on the bottom electrode;
forming a first reaction preventing film to cover at least the ferroelectric film;
planarizing the first reaction preventing film and the ferroelectric film to expose an upper surface of the ferroelectric film;
forming a top electrode on the ferroelectric film; and
forming a second reaction preventing film on the first reaction preventing film to cover a side surface and an upper surface of the upper electrode.
